(19) United States
(12) Patent Application Publication
(10) Pub. No.: US 2026/0255643 A1
(43) Pub. Date: Aug. 27, 2026

(54) NITRIDE SEMICONDUCTOR DEVICE

(71) Applicant: Panasonic Holdings Corporation, Osaka (JP)

(72) Inventors: SATOSHI TAMURA, Osaka (JP); MASAO KAWAGUCHI, Kyoto (JP)

(21) Appl. No.: 19/534,545

(22) Filed: Feb. 9, 2026

(30) Foreign Application Priority Data
Feb. 26, 2025 (JP) 2025-028866

(51) Int. Cl. H10D 62/824; H10D 30/47; H10D 62/10

(52) U.S. Cl. CPC H10D 62/824; H10D 30/475; H10D 30/4755; H10D 62/106

(57) ABSTRACT

A nitride semiconductor device includes a first nitride semiconductor layer, a second nitride semiconductor layer disposed above the first nitride semiconductor layer, the second nitride semiconductor layer having a band gap larger than a band gap of the first nitride semiconductor layer, a p-type nitride semiconductor layer disposed above the second nitride semiconductor layer, a first electrode disposed above the p-type nitride semiconductor layer, a second electrode electrically connected to the first nitride semiconductor layer, and intermediate layer disposed between the second and the p-type nitride semiconductor layers. The P-type nitride semiconductor layer includes the overlapping portion that overlaps the intermediate layer and a non-overlapping portion that does not overlap the intermediate layer. A shortest distance between the non-overlapping portion and the second electrode is shorter than a shortest distance between the overlapping portion and the second electrode. The first electrode is electrically connected to the non-overlapping portion.

### BACKGROUND

### 1. Technical Field

The present disclosure relates to a nitride semiconductor device.

### 2. Description of the Related Art

Patent Literature (PTL) 1 discloses a nitride semiconductor device including a two-dimensional electron gas (2DEG) as a channel. In the nitride semiconductor device disclosed in PTL 1, a p-type semiconductor layer is provided immediately below a gate electrode. The potential of a conduction band edge of the channel portion is raised by the p-type semiconductor layer, a threshold value can be increased, and normally-off operation of the transistor can be realized.

PTL 1: Japanese Patent No. 6511645

### SUMMARY

A nitride semiconductor device according to one aspect of the present disclosure includes a substrate, a first nitride semiconductor layer disposed above the substrate, a second nitride semiconductor layer disposed above the first nitride semiconductor layer, the second nitride semiconductor layer having a band gap larger than a band gap of the first nitride semiconductor layer, a third nitride semiconductor layer of p-type disposed above the second nitride semiconductor layer, a first electrode disposed above the third nitride semiconductor layer, a second electrode disposed above the substrate and electrically connected to the first nitride semiconductor layer, and an intermediate layer disposed between the second nitride semiconductor layer and the third nitride semiconductor layer. The third nitride semiconductor layer includes an overlapping portion that overlaps the intermediate layer in plan view of the substrate and a non-overlapping portion that does not overlap the intermediate layer in plan view of the substrate. A shortest distance between the non-overlapping portion and the second electrode is shorter than a shortest distance between the overlapping portion and the second electrode. The first electrode is electrically connected to the non-overlapping portion.

### BRIEF DESCRIPTION OF THE DRAWINGS

FIG. 1 is a cross-sectional view of a nitride semiconductor device according to a first exemplary embodiment;

FIG. 2 is a cross-sectional view of a nitride semiconductor device according to a second exemplary embodiment;

FIG. 3 is a cross-sectional view of a nitride semiconductor device according to a third exemplary embodiment;

FIG. 4 is a cross-sectional view of a nitride semiconductor device according to a fourth exemplary embodiment;

FIG. 5 is a cross-sectional view of a nitride semiconductor device according to a first modification of the fourth exemplary embodiment;

FIG. 6 is a cross-sectional view of a nitride semiconductor device according to a second modification of the fourth exemplary embodiment;

FIG. 7 is a cross-sectional view of a nitride semiconductor device according to a third modification of the fourth exemplary embodiment;

FIG. 8 is a cross-sectional view of a nitride semiconductor device according to a fifth exemplary embodiment;

FIG. 9 is a cross-sectional view of a nitride semiconductor device according to a sixth exemplary embodiment; and

FIG. 10 is a cross-sectional view of a nitride semiconductor device according to a seventh exemplary embodiment.

### DETAILED DESCRIPTIONS

The above-described conventional nitride semiconductor device has a problem that the concentration of the 2DEG decreases due to the influence of a depletion layer extending from the p-type semiconductor layer, and the on-resistance increases.

Therefore, the present disclosure provides a nitride semiconductor device capable of reducing on-resistance.

### Summary of present disclosure

A nitride semiconductor device according to a first aspect of the present disclosure includes a substrate, a first nitride semiconductor layer disposed above the substrate, a second nitride semiconductor layer disposed above the first nitride semiconductor layer, the second nitride semiconductor layer having a band gap larger than a band gap of the first nitride semiconductor layer, a third nitride semiconductor layer of p-type disposed above the second nitride semiconductor layer, a first electrode disposed above the third nitride semiconductor layer, a second electrode disposed above the substrate and electrically connected to the first nitride semiconductor layer, and an intermediate layer disposed between the second nitride semiconductor layer and the third nitride semiconductor layer. The third nitride semiconductor layer includes an overlapping portion that overlaps the intermediate layer in plan view of the substrate and a non-overlapping portion that does not overlap the intermediate layer in plan view of the substrate. A shortest distance between the non-overlapping portion and the second electrode is shorter than a shortest distance between the overlapping portion and the second electrode. The first electrode is electrically connected to the non-overlapping portion.

As a result, the 2DEG is generated in the vicinity of the interface between the first nitride semiconductor layer and the second nitride semiconductor layer, which can be used as a channel. In the region overlapping the non-overlapping portion of the p-type third nitride semiconductor layer in plan view, the potential of the conduction band edge of the channel can be increased. Thus, the nitride semiconductor device can be operated as a normally-off type transistor. Further, in the region overlapping the overlapping portion of the third nitride semiconductor layer in plan view, the influence of the third nitride semiconductor layer on the channel can be suppressed with the intermediate layer. A decrease in the concentration of the 2DEG can be suppressed, and the on-resistance can be reduced.

A nitride semiconductor device according to a second aspect of the present disclosure is the nitride semiconductor device according to the first aspect, the nitride semiconductor device including a fourth nitride semiconductor layer of n-type disposed above the substrate, a fifth nitride semiconductor layer of p-type disposed above the fourth nitride semiconductor layer, and a drain electrode disposed below the substrate. The first electrode is a gate electrode. The second electrode is a source electrode. The first nitride semiconductor layer and the second nitride semiconductor layer are disposed covering an inner surface of a first opening that penetrates the fifth nitride semiconductor layer and reaches the fourth nitride semiconductor layer and a portion above the fifth nitride semiconductor layer. The intermediate layer is provided at a position overlapping the first opening in plan view of the substrate.

This can realize a vertical transistor having a high breakdown voltage.

A nitride semiconductor device according to a third aspect of the present disclosure is the nitride semiconductor device according to the second aspect. The first electrode is disposed at a position overlapping the first opening in plan view of the substrate. The non-overlapping portion is provided continuously from the overlapping portion.

As a result, the magnitude of the threshold value of the transistor can be determined by the inclined portion along the side surface of the first opening and the flat portion outside the first opening. Normally, the side surface of the first opening serves as a semipolar surface. Thus, the concentration of the 2DEG tends to decrease as compared with the polar surface of the flat portion, and the threshold value tends to be higher in the inclined portion as compared with the flat portion. By providing the intermediate layer in an overlapping manner to the first opening, it is possible to suppress a decrease in the concentration of the 2DEG in the inclined portion and to lower the threshold value. That is, the difference in threshold value between the inclined portion and the flat portion can be reduced, and controllability of turning on and off the transistor can be enhanced.

A nitride semiconductor device according to a fourth aspect of the present disclosure is the nitride semiconductor device according to the second aspect, the nitride semiconductor device including a third electrode disposed above the third nitride semiconductor layer at a position overlapping the first opening in plan view of the substrate and electrically connected to the second electrode. The first electrode is disposed at a position overlapping the fifth nitride semiconductor layer without overlapping the first opening in plan view of the substrate.

As a result, the threshold value of the transistor is determined at the flat portion outside the first opening, and the threshold value is not affected by the inclined portion. Thus, controllability of turning on and off the transistor can be enhanced. In addition, by providing the third electrode electrically connected to the source electrode, the third electrode can terminate the line of electric force extending from the drain electrode. The parasitic capacitance between the gate and the drain can be reduced, and the switching speed can be increased.

A nitride semiconductor device according to a fifth aspect of the present disclosure is the nitride semiconductor device according to the fourth aspect. The third electrode is electrically connected to the overlapping portion. The non-overlapping portion is disposed apart from the overlapping portion.

As a result, a reverse bias can be applied to the pn junction between the p-type overlapping portion and the 2DEG via the third electrode and the drain electrode. Thus, the breakdown voltage of the vertical transistor can be increased.

A nitride semiconductor device according to a sixth aspect of the present disclosure is the nitride semiconductor device according to any one of the second to fifth aspects. The non-overlapping portion overlaps an upper surface of the fifth nitride semiconductor layer in plan view of the substrate.

As a result, variations in the thickness of the non-overlapping portion and the second nitride semiconductor layer can be suppressed in a range overlapping the upper surface of the fifth nitride semiconductor layer in plan view, and thus, the threshold value of the transistor can be stabilized.

A nitride semiconductor device according to a seventh aspect of the present disclosure is the nitride semiconductor device according to any one of the second to sixth aspects. The second nitride semiconductor layer includes a recess at a position overlapping an upper surface of the fifth nitride semiconductor layer in plan view of the substrate. The non-overlapping portion is disposed in contact with at least a part of a bottom surface of the recess.

As a result, the threshold value of the transistor can be adjusted by the depth of the recess. For example, normally-off operation of the transistor can be easily realized. In addition, portions of the second nitride semiconductor layer other than the recess can be thickened, and thus, the concentration of the 2DEG can be increased in the thickened portions. Thus, it is possible to achieve both the normally-off operation and the reduction in the on-resistance.

A nitride semiconductor device according to an eighth aspect of the present disclosure is the nitride semiconductor device according to the seventh aspect. An end of the non-overlapping portion on the second electrode side is positioned on the bottom surface of the recess.

This can prevent the 2DEG from being generated in the OFF state in the region immediately below the recess. Since the source-electrode-side end of the non-overlapping portion electrically connected to the gate electrode is positioned on the bottom surface of the recess, the area where the non-overlapping portion and the 2DEG face each other is reduced. Thus, the parasitic capacitance between the gate and the source can be reduced.

A nitride semiconductor device according to a ninth aspect of the present disclosure is the nitride semiconductor device according to any one of the fourth to eighth aspects. The second nitride semiconductor layer includes a recess at a position overlapping an upper surface of the fifth nitride semiconductor layer in plan view of the substrate. An end of the non-overlapping portion on the second electrode side and an end of the non-overlapping portion on a side opposite to the second electrode side are positioned on a bottom surface of the recess.

This can further reduce the parasitic capacitance between the gate and the source.

A nitride semiconductor device according to a tenth aspect of the present disclosure is the nitride semiconductor device according to any one of the second to ninth aspects. The second electrode is electrically connected to the fifth nitride semiconductor layer via a second opening that penetrates the second nitride semiconductor layer and the first nitride semiconductor layer and reaches the fifth nitride semiconductor layer.

As a result, a reverse bias can be applied to the pn junction between the p-type fifth nitride semiconductor layer and the n-type fourth nitride semiconductor layer via the source electrode and the drain electrode. Thus, the breakdown voltage of the vertical transistor can be increased.

A nitride semiconductor device according to an eleventh aspect of the present disclosure is the nitride semiconductor device according to the tenth aspect, the nitride semiconductor device including a sixth nitride semiconductor layer of p-type disposed in contact with the fifth nitride semiconductor layer in the second opening. The second electrode is in contact with the sixth nitride semiconductor layer.

Etching damage may occur in the fifth nitride semiconductor layer when the second opening is formed. Thus, when the fifth nitride semiconductor layer and the source electrode are brought into contact with each other, good contact cannot be obtained, and contact resistance may be increased. In contrast, according to the present aspect, the source electrode and the fifth nitride semiconductor layer are electrically connected via the sixth nitride semiconductor layer, and thus, the contact resistance can be reduced.

A nitride semiconductor device according to a twelfth aspect of the present disclosure is the nitride semiconductor device according to any one of the second to eleventh aspects. The intermediate layer does not overlap at least a part of a bottom surface of the first opening in plan view of the substrate.

As a result, there is a portion where the intermediate layer is not provided in a range overlapping the bottom surface of the first opening in plan view. Thus, electric field concentration generated when a reverse bias is applied between the drain and the source can be alleviated by the p-type third nitride semiconductor layer.

A nitride semiconductor device according to a thirteenth aspect of the present disclosure is the nitride semiconductor device according to any one of the first to twelfth aspects. The intermediate layer contains a nitride semiconductor as a main component.

As a result, the second nitride semiconductor layer and the intermediate layer can be continuously formed through epitaxial growth. Since a defect level is less likely to be formed at the interface, the operation of the transistor can be stabilized.

A nitride semiconductor device according to a fourteenth aspect of the present disclosure is the nitride semiconductor device according to any one of the first to thirteenth aspects. The intermediate layer has an n-type conductivity.

As a result, the potential of the conduction band edge of the channel raised by the p-type third nitride semiconductor layer can be pushed down by the n-type intermediate layer. Therefore, a decrease in the concentration of the 2DEG can be suppressed, and the on-resistance can be reduced. furthermore, the n-type intermediate layer can suppress diffusion of p-type impurities from the p-type third nitride semiconductor layer. It is possible to cancel the p-type conversion of the n-type intermediate layer due to the p-type impurities, and the expansion of a depletion region is suppressed. Therefore, a decrease in the concentration of the 2DEG can be suppressed, and the on-resistance can be reduced.

A nitride semiconductor device according to a fifteenth aspect of the present disclosure is the nitride semiconductor device according to any one of the first to thirteenth aspects. The intermediate layer has an i-type conductivity.

As a result, the i-type intermediate layer can suppress diffusion of p-type impurities from the p-type third nitride semiconductor layer. Since the expansion of a depletion region accompanying the expansion of a p-type region is suppressed, it is possible to suppress a decrease in the concentration of the 2DEG and to reduce the on-resistance.

A nitride semiconductor device according to a sixteenth aspect of the present disclosure is the nitride semiconductor device according to the fifteenth aspect. The intermediate layer contains a p-type impurity.

As a result, the i-type intermediate layer can suppress diffusion of p-type impurities.

A nitride semiconductor device according to a seventeenth aspect of the present disclosure is the nitride semiconductor device according to any one of the first to sixteenth aspects. The intermediate layer has a film thickness of from 22 nm to 150 nm inclusive.

This can effectively suppress diffusion of the p-type impurities.

Hereinafter, exemplary embodiments will be specifically described with reference to the drawings.

Note that the exemplary embodiment described hereinafter provides comprehensive or specific examples. Numerical values, shapes, materials, constituent elements, arrangement positions and connection modes of the constituent elements, steps, order of the steps, and the like shown in the following exemplary embodiment are merely examples, and are not intended to limit the present disclosure. Moreover, among the constituent elements in the following exemplary embodiments, constituent elements not recited in the independent claims are described as arbitrary constituent elements.

Furthermore, each of the drawings is a schematic diagram, and is not necessarily strictly illustrated. Therefore, for example, scales and the like are not necessarily matched in the respective drawings. Furthermore, in each drawing, substantially identical components are denoted by identical reference signs, and the redundant description will be omitted or simplified.

Furthermore, in the present specification, the term indicating the relationship between elements such as parallel and orthogonal, the term indicating the shape of an element such as a rectangle, and the numerical range are not expressions representing only a strict meaning, but are expressions meaning to include a substantially equivalent range, for example, a difference of about several %.

Furthermore, in the present specification, a “thickness direction” of the substrate refers to a direction perpendicular to a principal surface of the substrate. The thickness direction is the same as a stacking direction of the semiconductor layers, and is also referred to as “vertical direction”. Furthermore, a direction parallel to the principal surface of the substrate may be referred to as “horizontal direction”. The “vertical” semiconductor device means a device in which a main path of a current such as a drain current or a forward current is vertical, that is, a device in which a main current passes through the substrate in the vertical direction. A “horizontal” semiconductor device means a device in which the main path of a current such as a drain current or a forward current is horizontal, that is, a device in which the main current does not pass through the substrate.

Furthermore, a side on which a heterostructure that generates the 2DEG is provided with respect to the substrate is regarded as “above” or “upper side”, and the opposite side is regarded as “below” or “lower side”. Note that, in the present specification, the terms “above” and “below” do not refer to an upward direction (vertically upward) and a downward direction (vertically downward) in absolute space recognition, but are used as terms defined by a relative positional relationship based on a stacking order in a stacking configuration. Furthermore, the terms “above” and “below” are not only applied to a case where two constituent elements are spaced apart from each other and another constituent element is present between the two constituent elements, but are also applied to a case where two constituent elements are disposed in close contact with each other and are adjacent to each other.

Furthermore, in the present specification, unless otherwise specified, “plan view” refers to when viewed from a direction perpendicular to the principal surface of the substrate of the semiconductor device, that is, when the principal surface of the substrate is viewed from the front.

Furthermore, in the present specification, “A and B overlap in plan view” means that at least a part of A and at least a part of B overlap. That is, a case where only a part of A and only a part of B overlap, a case where all of A overlap B, a case where all of B overlap A, and a case where A and B completely overlap each other are included.

Furthermore, the n-type and the p-type indicate the conductivity types of the semiconductor, and are conductivity types having opposite polarities to each other. The n⁺-type represents a state in which an n-type dopant is added to a semiconductor at a high concentration, that is, a so-called heavy dope. Furthermore, the n⁻-type represents a state in which an n-type dopant is added to a semiconductor at a low concentration, that is, so-called light doping. Both the n⁺-type and the n⁻-type are examples of the n-type, and the n⁺-type and the n⁻-type may be described as the n-type without being distinguished from each other. Furthermore, the same applies to the p-type, the p⁺-type, and the p⁻-type.

Furthermore, in the present specification, the “main component” means a component having the highest content rate among all the components constituting a member. For example, a component having a content rate of more than or equal to 50%e is a main component. The component is a material, an element, a compound, or the like.

Furthermore, in the present specification, AlGaN represents ternary mixed crystal AlₓGa₁₋ₓN (0 < x < 1). Hereinafter, a multicomponent mixed crystal is abbreviated as an arrangement of constituent element symbols, such as AlInN, GaInN, or the like. For example, AlₓGa_{1-x-y}In_{y}N (0 < x < 1, 0 < y < 1, and 0 < x + y < 1), which is an example of a nitride semiconductor, is abbreviated as AlGaInN. x, 1 - x - y, and y represent composition ratios of Al, Ga, and In, respectively.

Furthermore, in the present specification, ordinal numbers such as “first” and “second” do not mean the number or order of constituent elements unless otherwise specified, and are used for the purpose of avoiding confusion and distinguishing the same kind of constituent elements.

### First exemplary embodiment

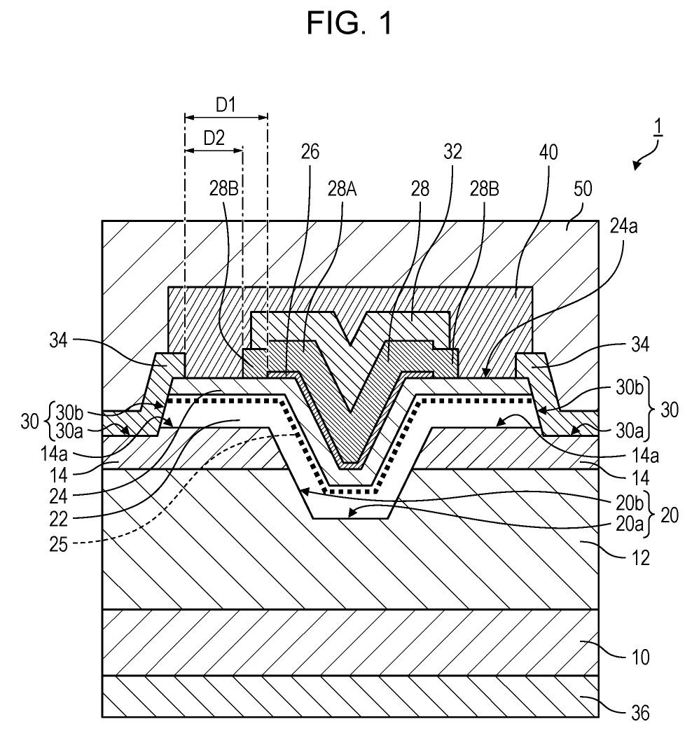

First, a configuration of a nitride semiconductor device according to a first exemplary embodiment will be described with reference to FIG. 1.

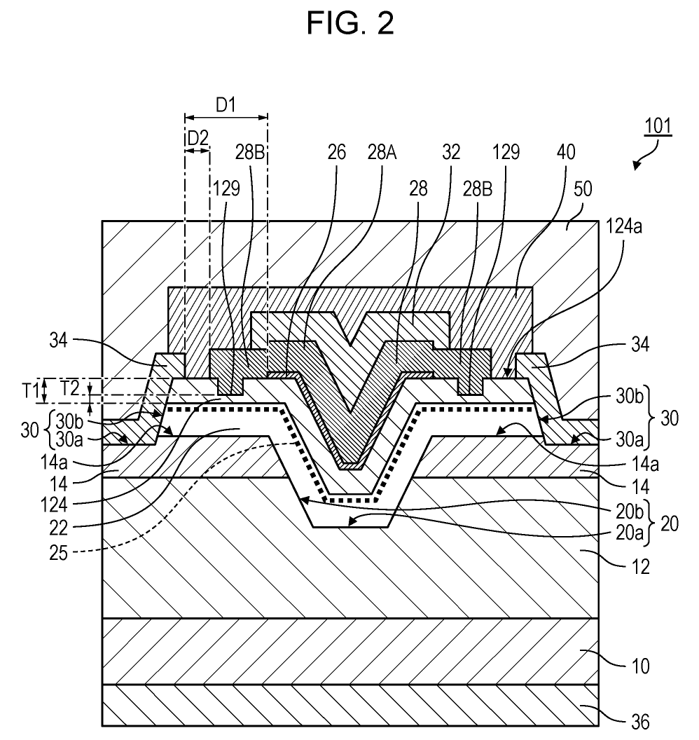

FIG. 1 is a cross-sectional view of nitride semiconductor device 1 according to the present exemplary embodiment. In FIG. 1, each constituent element such as a semiconductor layer, an insulating layer, and an electrode included in nitride semiconductor device 1 is shaded with diagonal lines representing the cross section. Note that, for electron transport layer 22, the shading of diagonal lines representing cross sections is omitted. The same applies to other cross-sectional views from FIG. 2 onwards.

Nitride semiconductor device 1 illustrated in FIG. 1 is a normally-off type vertical field effect transistor (FET). In nitride semiconductor device 1, for example, source electrode 34 is grounded, and a positive potential is applied to drain electrode 36. The potential applied to drain electrode 36 is, for example, from 100 V to 1200 V inclusive, but is not limited thereto. Nitride semiconductor device 1 performs a modulation operation according to the potential applied to gate electrode 32. For example, in a case where 0 V or a negative potential (for example, -5 V) is applied to gate electrode 32, no current flows between drain electrode 36 and source electrode 34. That is, nitride semiconductor device 1 goes into a non-conductive state (off). When a positive potential (for example, +5 V) is applied to gate electrode 32, a current flows from drain electrode 36 to source electrode 34. That is, nitride semiconductor device 1 is brought into a conductive state (on). The current flowing from drain electrode 36 to source electrode 34 when on is referred to as drain current. The drain current flows through substrate 10 in a thickness direction (that is, in a vertical direction).

As illustrated in FIG. 1, nitride semiconductor device 1 includes substrate 10, drift layer 12, block layer 14, electron transport layer 22, electron supply layer 24, intermediate layer 26, p-type semiconductor layer 28, gate electrode 32, source electrode 34, and drain electrode 36. Nitride semiconductor device 1 further includes insulating film 40 and source wiring 50. Nitride semiconductor device 1 is provided with first opening 20 and second opening 30.

Nitride semiconductor device 1 is a device in which a semiconductor layer including a channel contains a nitride semiconductor as a main component. Specifically, each of drift layer 12, block layer 14, electron transport layer 22, electron supply layer 24, intermediate layer 26, and p-type semiconductor layer 28 contains a nitride semiconductor as a main component.

Hereinafter, details of each constituent element included in nitride semiconductor device 1 will be described.

Substrate 10 is, for example, a substrate including n⁺-type GaN having a thickness of 300 μm and a carrier concentration of 5 × 10¹⁸ cm⁻³ as a main component.

Note that substrate 10 may not be a nitride semiconductor substrate. For example, substrate 10 may be a Si substrate, a SiC substrate, a ZnO substrate, or the like.

Drift layer 12 is an example of an n-type fourth nitride semiconductor layer, and is provided above substrate 10. Drift layer 12 is, for example, a film including n⁻-type GaN having a thickness of 8 μm as a main component. A donor concentration of drift layer 12 is, for example, from 1 × 10¹⁵ cm⁻³ to 1 × 10¹⁷ cm⁻³ inclusive, and is, as an example, 1 × 10¹⁶ cm⁻³. Furthermore, the carbon concentration (C concentration) of drift layer 12 is, for example, from 1 × 10¹⁵ cm⁻³ to 5 × 10¹⁶ cm⁻³ inclusive. Drift layer 12 is provided, for example, in contact with an upper surface (principal surface) of substrate 10.

Block layer 14 is an example of a p-type fifth nitride semiconductor layer, and is provided above drift layer 12. Block layer 14 is, for example, a film including, as a main component, p-type GaN having a thickness of 400 nm and a carrier concentration of 1 × 10¹⁷ cm⁻³. Block layer 14 is provided in contact with an upper surface of drift layer 12.

Block layer 14 is provided with first opening 20. First opening 20 penetrates block layer 14 to reach drift layer 12. First opening 20 may be referred to as a gate opening or a vertical conduction opening. Bottom surface 20a of first opening 20 is a part of the upper surface of drift layer 12. As illustrated in FIG. 1, bottom surface 20a is located on a lower side than a lower surface of block layer 14. Note that the lower surface of block layer 14 corresponds to an interface between block layer 14 and drift layer 12. Bottom surface 20a is, for example, parallel to the principal surface of substrate 10. When nitride semiconductor device 1 is on, a drain current flows between drain electrode 36 and source electrode 34 through bottom surface 20a of this first opening 20.

In the present exemplary embodiment, first opening 20 is formed such that an opening area increases with increasing distance from substrate 10. Specifically, side surface 20b of first opening 20 is inclined obliquely. As illustrated in FIG. 1, the cross-sectional view shape of first opening 20 is an inverted trapezoid, more specifically, an inverted isosceles trapezoid.

An inclination angle of side surface 20b with respect to bottom surface 20a is, for example, from 20° to 80° inclusive, but may be from 30° to 45° inclusive. Since side surface 20b approaches a c-plane as the inclination angle decreases, the film quality of electron transport layer 22 and the like formed along side surface 20b by crystal regrowth can be improved. On the other hand, as the inclination angle is larger, first opening 20 is suppressed from becoming too large, and miniaturization of nitride semiconductor device 1 is realized. Note that side surface 20b may be perpendicular to bottom surface 20a.

Electron transport layer 22 is an example of a first nitride semiconductor layer, and is provided above substrate 10. Specifically, electron transport layer 22 is also an example of a first regrowth layer, and is provided so as to cover an inner surface of first opening 20 and above block layer 14. For example, a part of electron transport layer 22 is provided along bottom surface 20a and side surface 20b of first opening 20, and the other part of electron transport layer 22 is provided on upper surface 14a of block layer 14. A thickness of electron transport layer 22 is, for example, from 50 nm to 500 nm inclusive. Electron transport layer 22 is, for example, a film including undoped GaN having a thickness of 150 nm as a main component. Note that the thickness of electron transport layer 22 is regarded as a thickness on an outer side of first opening 20 in plan view of substrate 10, that is, at a flat portion that is a portion overlapping upper surface 14a of block layer 14. Furthermore, electron transport layer 22 is assumed to be undoped, but may be partially made into an n-type by Si doping or the like.

Electron transport layer 22 is in contact with drift layer 12 on bottom surface 20a and side surface 20b of first opening 20. Furthermore, electron transport layer 22 is in contact with block layer 14 on side surface 20b of first opening 20. Specifically, electron transport layer 22 is in contact with upper surface 14a of block layer 14.

Electron transport layer 22 includes a channel. Specifically, 2DEG 25 serving as a channel is generated in the vicinity of an interface between electron transport layer 22 and electron supply layer 24. 2DEG 25 is bent along the interface between electron transport layer 22 and electron supply layer 24, that is, along the inner surface of first opening 20.

Although not illustrated in FIG. 1, an AlN layer having a thickness of about 1 nm is provided as a second regrowth layer between electron transport layer 22 and electron supply layer 24. As a result, alloy scattering is suppressed, channel mobility is improved, and on-resistance can be reduced. Note that the AlN layer is not necessarily required.

Electron supply layer 24 is an example of a second nitride semiconductor layer, and is provided above electron transport layer 22. Specifically, electron supply layer 24 is also an example of a third regrowth layer, and is provided so as to cover the inner surface of first opening 20 and above block layer 14. Specifically, electron supply layer 24 is provided along an upper surface of electron transport layer 22 so as to overlap bottom surface 20a and side surface 20b of first opening 20 and upper surface 14a of block layer 14 in plan view of substrate 10.

Electron supply layer 24 has a band gap larger than that of electron transport layer 22. Therefore, an AlGaN/GaN hetero interface is formed between electron supply layer 24 and electron transport layer 22. Electron supply layer 24 supplies electrons to the channel (2DEG 25) formed in electron transport layer 22.

Electron supply layer 24 is, for example, a film having a thickness of 22 nm and including undoped AlGaN as a main component. Electron supply layer 24 is formed in a shape along the upper surface of electron transport layer 22 and has a substantially uniform thickness. Note that a thickness of electron supply layer 24 is regarded as a thickness on the outer side of first opening 20 in plan view of substrate 10, that is, at a flat portion that is the portion overlapping upper surface 14a of block layer 14.

Note that, in a case where electron supply layer 24 includes AlGaN having an Al composition ratio of 20% as a main component, cracks are likely to occur when the thickness of electron supply layer 24 exceeds 70 nm. For this reason, the film quality of electron supply layer 24 is deteriorated, which may cause leakage, or 2DEG 25 may not be generated at a desired concentration. In a case where the Al composition ratio is lowered, generation of cracks can be suppressed, so that the thickness of electron supply layer 24 is, for example, from 10 nm to 150 nm inclusive. The Al composition ratio of electron supply layer 24 is not particularly limited, but is, for example, from 10% to 30% inclusive.

Intermediate layer 26 is provided between electron supply layer 24 and p-type semiconductor layer 28. Specifically, intermediate layer 26 is provided in contact with each of upper surface 24a of electron supply layer 24 and the lower surface of p-type semiconductor layer 28. In addition, in the present exemplary embodiment, the side surface of intermediate layer 26 is covered in contact with p-type semiconductor layer 28. Intermediate layer 26 is provided at a position overlapping first opening 20 in plan view of substrate 10. Specifically, intermediate layer 26 is provided at a position overlapping bottom surface 20a and side surface 20b of first opening 20 in plan view of substrate 10. A part of intermediate layer 26 may overlap the outside of first opening 20, that is, upper surface 14a of block layer 14 in plan view of substrate 10. The end of intermediate layer 26 on source electrode 34 side may overlap upper surface 14a of block layer 14 or may overlap the inclined side surface of block layer 14 in plan view of substrate 10. Intermediate layer 26 is formed in a shape along upper surface 24a of electron supply layer 24 and has a substantially uniform thickness.

Intermediate layer 26 includes a nitride semiconductor as a main component. In the present exemplary embodiment, the conductivity type of intermediate layer 26 is n-type. Specifically, intermediate layer 26 is a film including n-type GaN as a main component. The carrier concentration of intermediate layer 26 is, for example, more than or equal to 2 × 10¹⁷ cm⁻³. As a result, the concentration of 2DEG 25 can be increased. The carrier concentration of intermediate layer 26 may be, for example, less than or equal to 1 × 10²⁰ cm⁻³. The concentration of 2DEG 25 is substantially saturated when the carrier concentration of intermediate layer 26 is in a range of more than or equal to 5 × 10¹⁸ cm⁻³.

The film thickness of intermediate layer 26 is, for example, from 22 nm to 150 nm inclusive. Since the concentration of 2DEG 25 rapidly increases when the film thickness of intermediate layer 26 is in the range from 22 nm to 50 nm inclusive, the effect of reducing the on-resistance is high. On the other hand, the concentration of 2DEG 25 is substantially saturated when the film thickness of intermediate layer 26 is in the range from 100 nm to 150 nm inclusive. Thus, it is possible to prevent intermediate layer 26 from becoming thicker than necessary, and it is possible to suppress the occurrence of disconnection of p-type semiconductor layer 28 and gate electrode 32 formed above. In addition, the time required for forming intermediate layer 26 can be shortened.

P-type semiconductor layer 28 is an example of a p-type third nitride semiconductor layer, and is provided above electron supply layer 24. As illustrated in FIG. 1, p-type semiconductor layer 28 includes overlapping portion 28A and non-overlapping portion 28B. In the present exemplary embodiment, non-overlapping portion 28B is provided continuously from overlapping portion 28A.

Overlapping portion 28A is a portion overlapping intermediate layer 26 in plan view of substrate 10. The plan view shape and size of overlapping portion 28A are matched with those of intermediate layer 26. Overlapping portion 28A is provided in contact with each of the upper surface of intermediate layer 26 and the lower surface of gate electrode 32.

Non-overlapping portion 28B is a portion that does not overlap intermediate layer 26 in plan view of substrate 10. Non-overlapping portion 28B is provided in contact with each of upper surface 24a of electron supply layer 24 and the lower surface of gate electrode 32. The upper surface of non-overlapping portion 28B does not have to be in contact with gate electrode 32.

P-type semiconductor layer 28 is, for example, a film having a thickness of 50 nm, having a carrier concentration of 5 × 10¹⁷ cm⁻³ and containing p-type GaN as a main component. The thickness of p-type semiconductor layer 28 is, for example, from 5 nm to 500 nm inclusive. The thickness and the carrier concentration of p-type semiconductor layer 28 are merely examples, and they can be appropriately changed. For example, p-type semiconductor layer 28 may be a film containing p-type AlGaN as a main component. Overlapping portion 28A and non-overlapping portion 28B may be different from each other in at least one of the thickness, the composition, and the carrier concentration.

As illustrated in FIG. 1, shortest distance D2 between non-overlapping portion 28B and source electrode 34 is shorter than shortest distance D1 between overlapping portion 28A and source electrode 34. Both shortest distances D1 and D2 are distances in a gate length direction. The gate length direction is a direction in which gate electrode 32 and source electrode 34 are arranged, and is a left-right direction in the drawing in the example illustrated in FIG. 1. Non-overlapping portion 28B is positioned between overlapping portion 28A and source electrode 34. In the present exemplary embodiment, non-overlapping portion 28B is a portion of p-type semiconductor layer 28 that protrudes from intermediate layer 26 toward source electrode 34 in plan view.

Second opening 30 penetrates electron supply layer 24 and electron transport layer 22 and reaches block layer 14. Second opening 30 may be referred to as source opening. Second opening 30 is provided at a position away from both gate electrode 32 and p-type semiconductor layer 28 in plan view of substrate 10. Since second opening 30 penetrates electron transport layer 22, 2DEG 25 is exposed on side surface 30b of second opening 30. Second opening 30 and source electrode 34 are provided on both sides outside first opening 20 in the cross-sectional view illustrated in FIG. 1.

Bottom surface 30a of the second opening 30 is a part of upper surface 14a of block layer 14. Bottom surface 30a is, for example, parallel to the principal surface of substrate 10. In the example illustrated in FIG. 1, bottom surface 30a is located on a lower side than a lower surface of electron transport layer 22. Note that the lower surface of electron transport layer 22 corresponds to an interface between electron transport layer 22 and block layer 14.

Furthermore, as illustrated in FIG. 1, second opening 30 is formed such that an opening area increases as a distance from substrate 10 increases. Specifically, side surface 30b of second opening 30 is inclined obliquely. At this time, an inclination angle of side surface 30b with respect to bottom surface 30a is, for example, in a range from 30° to 60° inclusive. Since side surface 30b is inclined obliquely, a contact area between source electrode 34 and 2DEG 25 increases, so that ohmic connection is easily performed. Note that 2DEG 25 is exposed to side surface 30b of second opening 30, and is connected to source electrode 34 at an exposed portion. Furthermore, side surface 30b may be perpendicular to bottom surface 30a.

Since second opening 30 is provided, ohmic contact resistance between 2DEG 25 functioning as a channel and source electrode 34 can be reduced. That is, the on-resistance of nitride semiconductor device 1 can be reduced.

Furthermore, source electrode 34 and block layer 14 are electrically connected to each other at bottom surface 30a of second opening 30. As a result, the same potential as a potential applied to source electrode 34 is supplied to block layer 14. In a case where a reverse voltage is applied to the pn junction formed by block layer 14 and drift layer 12, specifically, in a case where drain electrode 36 has a higher potential than source electrode 34, a depletion layer extends to drift layer 12, so that the withstand voltage of nitride semiconductor device 1 can be increased.

Gate electrode 32 is an example of a first electrode, and is provided above p-type semiconductor layer 28. Specifically, gate electrode 32 is provided in contact with the upper surface of overlapping portion 28A and the upper surface of non-overlapping portion 28B of p-type semiconductor layer 28. Gate electrode 32 is electrically connected to non-overlapping portion 28B. In the present exemplary embodiment, overlapping portion 28A and non-overlapping portion 28B are continuous. Thus, gate electrode 32 is also electrically connected to overlapping portion 28A. Gate electrode 32 is in contact with at least either overlapping portion 28A or non-overlapping portion 28B.

Gate electrode 32 is provided at a position overlapping first opening 20 in plan view of substrate 10. Specifically, gate electrode 32 overlaps bottom surface 20a and side surface 20b of first opening 20 in plan view of substrate 10. Gate electrode 32 is disposed apart from the source electrode 34, and is electrically separated from source electrode 34.

Gate electrode 32 is formed using, for example, a conductive material such as metal. For example, gate electrode 32 may be made of a material such as p-type GaN which is ohmic-connected to a p-type nitride semiconductor, but is not limited thereto, and may be made of a material which is Schottky connected to a p-type nitride semiconductor. For example, Pd, a Ni-based material, WSi, Au, or the like can be used as a material for forming gate electrode 32.

Source electrode 34 is an example of a second electrode, and is provided above substrate 10. In the present exemplary embodiment, source electrode 34 is electrically connected to block layer 14 via second opening 30. Furthermore, source electrode 34 is electrically connected to electron transport layer 22 via second opening 30. Specifically, source electrode 34 is provided in contact with bottom surface 30a and side surface 30b of second opening 30. Source electrode 34 is in contact with block layer 14 at bottom surface 30a of second opening 30. Source electrode 34 is in contact with 2DEG 25 on side surface 30b of second opening 30. As a result, the contact resistance between source electrode 34 and 2DEG 25 can be reduced, so that the on-resistance of nitride semiconductor device 1 can be reduced.

Source electrode 34 is formed using a conductive material such as metal. As a material of source electrode 34, for example, a material that is ohmic-connected to an n-type nitride semiconductor such as n-type GaN by heat treatment, such as Ti/Al (stacked structure of Ti layer and Al layer), can be used.

Drain electrode 36 is provided below substrate 10. Specifically, drain electrode 36 is provided in contact with the lower surface of substrate 10.

Drain electrode 36 is formed using a conductive material such as metal. As the material of drain electrode 36, similarly to the material of source electrode 34, for example, a material such as Ti/Al that is ohmic-connected to an n-type nitride semiconductor such as n-type GaN can be used.

Insulating film 40 is provided above gate electrode 32. Specifically, insulating film 40 is provided so as to cover gate electrode 32, p-type semiconductor layer 28, electron supply layer 24, and source electrode 34. Insulating film 40 has a stacked structure of a plurality of insulating films. The plurality of insulating films is, for example, insulating films of SiN, SiO₂, SiON, Al₂O₃, or the like. Note that insulating film 40 may have a single-layer structure of one insulating film.

Source wiring 50 is provided above insulating film 40, and is connected to source electrode 34 via an opening provided in insulating film 40. Source wiring 50 is formed using a conductive material such as metal. For example, source wiring 50 is a plated film made of Au, for example.

In nitride semiconductor device 1 configured as described above, 2DEG 25 is generated in the vicinity of the interface between electron transport layer 22 and electron supply layer 24, and can be used as a channel. In a region overlapping non-overlapping portion 28B of p-type semiconductor layer 28 in plan view, the potential of the conduction band edge of the channel can be increased. Therefore, nitride semiconductor device 1 can be operated as a normally-off transistor. Further, in a region overlapping overlapping portion 28A of p-type semiconductor layer 28 in plan view, the influence of p-type semiconductor layer 28 on the channel can be suppressed with intermediate layer 26. That is, a decrease in the concentration of 2DEG 25 can be suppressed, and the on-resistance can be reduced.

The magnitude of the threshold value of the transistor can be determined by the inclined portion of the channel along side surface 20b of first opening 20 and the flat portion of the channel outside first opening 20. Normally, side surface 20b of first opening 20 serves as a semipolar surface. Thus, the concentration of 2DEG 25 tends to decrease as compared with the polar surface of the flat portion, and the threshold value tends to be higher in the inclined portion as compared with the flat portion. By providing intermediate layer 26 in an overlapping manner to first opening 20, it is possible to suppress a decrease in the concentration of 2DEG 25 in the inclined portion and to lower the threshold value. That is, the difference in threshold value between the inclined portion and the flat portion can be reduced, and controllability of turning on and off the transistor can be enhanced.

A manufacturing method of nitride semiconductor device 1 is not particularly limited, but for example, the following manufacturing method can be used.

First, a nitride semiconductor is crystal-grown by epitaxial growth on the principal surface of substrate 10 to form a plurality of nitride semiconductor films. Specifically, drift layer 12 and block layer 14 are formed in this order on the principal surface of substrate 10. In the epitaxial growth, the composition, thickness, conductivity type, impurity concentration, and the like of each of the nitride semiconductor films can be adjusted by adjusting growth conditions such as a raw material, a growth temperature, and a growth time.

Thereafter, a part of block layer 14 is removed to form first opening 20. For example, block layer 14 is removed by photolithography, dry etching, or the like. At this time, by removing a part of a surface layer portion of drift layer 12 continuously from the removal of block layer 14, bottom surface 20a of first opening 20 is formed below the interface between block layer 14 and drift layer 12 as illustrated in FIG. 1.

Next, a nitride semiconductor is crystal-grown by the second epitaxial growth so as to cover bottom surface 20a and side surface 20b of first opening 20 and upper surface 14a of block layer 14. Specifically, electron transport layer 22, electron supply layer 24, and intermediate layer 26 are formed in this order.

Next, second opening 30 is formed by removing a part of each of intermediate layer 26, electron supply layer 24, and electron transport layer 22. For example, each layer is removed by photolithography, dry etching, or the like. At this time, by removing a part of a surface layer portion of block layer 14 continuously from the removal of electron transport layer 22, bottom surface 30a of second opening 30 is formed below the interface between block layer 14 and electron transport layer 22 as illustrated in FIG. 1. Moreover, by removing a part of intermediate layer 26, intermediate layer 26 is patterned into a predetermined shape. As a result, a part of upper surface 24a of electron supply layer 24 is exposed without being covered with intermediate layer 26.

Next, a nitride semiconductor is crystal-grown by the third epitaxial growth so as to cover intermediate layer 26. Specifically, p-type semiconductor layer 28 is formed so as to cover intermediate layer 26. Thereafter, p-type semiconductor layer 28 is patterned into a predetermined shape by removing a part of p-type semiconductor layer 28. As a result, a part of upper surface 24a of electron supply layer 24 is exposed without being covered with p-type semiconductor layer 28. At this time, p-type semiconductor layer 28 is patterned such that overlapping portion 28A overlapping intermediate layer 26 in plan view and non-overlapping portion 28B not overlapping intermediate layer 26 remain.

Next, gate electrode 32, and source electrode 34 are formed. For example, first, a conductive film is formed using a conductive material ohmic-connected to an n-type nitride semiconductor, and then patterned into a predetermined shape to form source electrode 34. The conductive film is formed by sputtering or vapor deposition. Patterning of the conductive film is performed by etching, a lift-off method, or the like. Source electrode 34 is formed so as to contact and cover bottom surface 30a and side surface 30b of second opening 30 and not to contact p-type semiconductor layer 28. Next, a conductive film is formed using a conductive material ohmic-connected to a p-type nitride semiconductor, and then patterned into a predetermined shape to form gate electrode 32. Formation and patterning of the conductive film are the same as in the case of source electrode 34. Gate electrode 32 is formed on the upper surface of p-type semiconductor layer 28 so as not to be in contact with upper surface 24a of electron supply layer 24 or source electrode 34.

Gate electrode 32 may be formed before source electrode 34 is formed. Furthermore, for example, after gate electrode 32 is patterned, p-type semiconductor layer 28 may be patterned using gate electrode 32 as a mask. Furthermore, in a case where gate electrode 32, and source electrode 34 are formed using the same conductive material, gate electrode 32, and source electrode 34 may be formed in the same process.

Next, insulating film 40 and source wiring 50 are formed. Insulating film 40 is formed by a plasma chemical vapor deposition (CVD) method, an atomic layer deposition (ALD) method, a coating method, or the like. Source electrode 34 is exposed by etching insulating film 40 after the film deposition. Thereafter, source wiring 50 is formed by a plating method or the like. Note that, although not illustrated in FIG. 1, the gate wiring electrically connected to gate electrode 32 can also be formed in the same manner as source wiring 50.

Next, drain electrode 36 is formed on the lower surface of substrate 10. For example, drain electrode 36 is formed by forming a conductive film using a conductive material ohmic-connected to an n-type nitride semiconductor. The conductive film is formed by sputtering or vapor deposition.

Through the above processes, nitride semiconductor device 1 illustrated in FIG. 1 can be manufactured.

### Second exemplary embodiment

Subsequently, a second exemplary embodiment will be described.

The second exemplary embodiment is mainly different from the first exemplary embodiment in that a recess is provided in the electron supply layer. Hereinafter, differences from the first exemplary embodiment will be mainly described, and description of common points will be omitted or simplified.

FIG. 2 is a cross-sectional view of nitride semiconductor device 101 according to the present exemplary embodiment. Nitride semiconductor device 101 illustrated in FIG. 2 includes electron supply layer 124 instead of electron supply layer 24 as compared with nitride semiconductor device 1 illustrated in FIG. 1.

Electron supply layer 124 is provided with recess 129. Recess 129 is provided at a position overlapping upper surface 14a of block layer 14 in plan view of substrate 10. Part or all of recess 129 may overlap side surface 20b of first opening 20 in plan view of substrate 10. Recess 129 is a recess recessed from upper surface 124a of electron supply layer 124 toward substrate 10. A side surface of recess 129 is perpendicular to a bottom surface of recess 129, but it may be inclined obliquely.

P-type semiconductor layer 28 is provided so as to cover recess 129. Intermediate layer 26 is not provided in recess 129. That is, non-overlapping portion 28B of p-type semiconductor layer 28 covers recess 129. The length of non-overlapping portion 28B in the gate length direction corresponds to D1-D2, and is longer than the length of recess 129 in the gate length direction. In the present exemplary embodiment, the end of intermediate layer 26 on source electrode 34 side is positioned away from the open end of recess 129, but the present disclosure is not limited to this example. The end of intermediate layer 26 on source electrode 34 side may be matched with the opening end of recess 129. That is, the side surface of intermediate layer 26 and the side surface of recess 129 may be flush with each other.

In the portion where recess 129 is provided, the thickness of electron supply layer 124 is reduced. As illustrated in FIG. 2, thickness T2 of the portion of electron supply layer 124 where recess 129 is provided is thinner than thickness T1 of the portion where recess 129 is not provided.

As thickness T2 decreases, the concentration of 2DEG 25 in the direction immediately below recess 129 decreases. Thus, the threshold value of the transistor can be increased. For example, the threshold value can be made higher than 0 V, which facilitates normally-off operation of the transistor. By adjusting the value of thickness T2, the threshold value of the transistor can be determined. For example, thickness T2 is from 10 nm to 40 nm inclusive, for example, 22 nm.

The portion of electron supply layer 124 where recess 129 is not provided can be thickened without affecting the threshold value of the transistor. Thus, the density of 2DEG 25 in the direction immediately below the portion where recess 129 is not provided increases, and thus, the on-resistance can be reduced. For example, thickness T1 is from 10 nm to 70 nm inclusive, for example, 60 nm. By providing recess 129 in this manner, it is possible to achieve both the normally-off operation and the reduction of the on-resistance.

Recess 129 is formed by removing a part of electron supply layer 124 after forming electron supply layer 124 and before forming p-type semiconductor layer 28. Electron supply layer 124 is removed by etching.

### Third exemplary embodiment

Subsequently, a third exemplary embodiment will be described.

The third exemplary embodiment is different from the second exemplary embodiment mainly in that a part of the bottom surface of the recess is not covered with a p-type semiconductor layer. Hereinafter, differences from the second exemplary embodiment will be mainly described, and description of common points will be omitted or simplified.

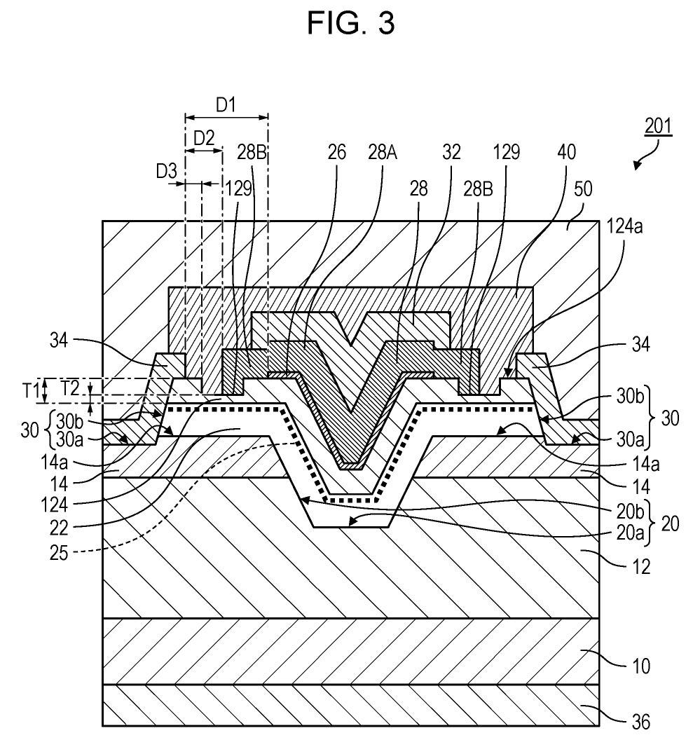

FIG. 3 is a cross-sectional view of nitride semiconductor device 201 according to the present exemplary embodiment. In nitride semiconductor device 201 illustrated in FIG. 3, the position of the end of p-type semiconductor layer 28 on source electrode 34 side is mainly different from that in nitride semiconductor device 101 illustrated in FIG. 2.

Specifically, the end of p-type semiconductor layer 28 on source electrode 34 side is positioned on the bottom surface of recess 129. That is, a part of the bottom surface of recess 129 is covered with non-overlapping portion 28B of p-type semiconductor layer 28, and the other part of the bottom surface of recess 129 is covered with insulating film 40 without being covered with p-type semiconductor layer 28. Shortest distance D3 between recess 129 and source electrode 34 is shorter than shortest distance D2 between non-overlapping portion 28B and source electrode 34. Shortest distance D3 may be 0. The side surface of recess 129 on source electrode 34 side does not have to be provided. A part of source electrode 34 may be provided away from p-type semiconductor layer 28 in recess 129.

In nitride semiconductor device 201 according to the present exemplary embodiment, the concentration of 2DEG 25 decreases in a region immediately below recess 129, and 2DEG 25 can be eliminated in an OFF state. Since the area in which non-overlapping portion 28B electrically connected to gate electrode 32 and 2DEG 25 face each other is reduced, parasitic capacitance Cgs between the gate and the source can be reduced.

### Fourth exemplary embodiment

Subsequently, a fourth exemplary embodiment will be described.

The fourth exemplary embodiment is different from the first exemplary embodiment mainly in that a gate electrode is provided at a position not overlapping with the first opening in plan view and a shielding electrode is provided at a position overlapping with the first opening. Hereinafter, differences from the first exemplary embodiment will be mainly described, and description of common points will be omitted or simplified.

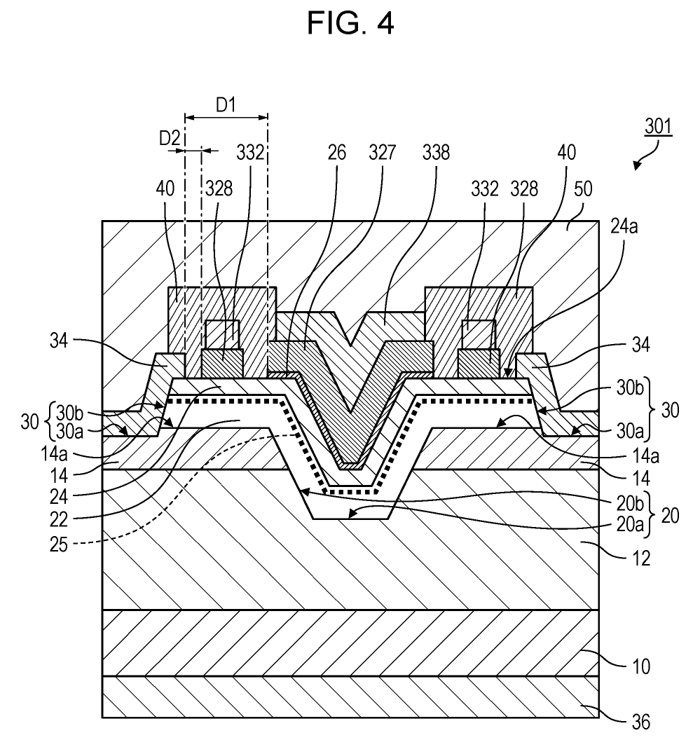

FIG. 4 is a cross-sectional view of nitride semiconductor device 301 according to the present exemplary embodiment. As compared with nitride semiconductor device 1 illustrated in FIG. 1, nitride semiconductor device 301 illustrated in FIG. 4 includes shielding layer 327, threshold value adjustment layer 328, gate electrode 332, and shielding electrode 338 instead of p-type semiconductor layer 28 and gate electrode 32.

Shielding layer 327 is an example of an overlapping portion of the p-type third nitride semiconductor layer, is provided above electron supply layer 24, and overlaps intermediate layer 26 in plan view of substrate 10. Shielding layer 327 overlaps bottom surface 20a and side surface 20b of first opening 20 in plan view of substrate 10. The plan view shape and size of shielding layer 327 are matched with those of intermediate layer 26. The side surface of shielding layer 327 is flush with the side surface of intermediate layer 26. Shielding layer 327 is provided in contact with each of the upper surface of intermediate layer 26 and the lower surface of shielding electrode 338. Shielding layer 327 is electrically connected to shielding electrode 338.

Threshold value adjustment layer 328 is an example of a non-overlapping portion of the p-type third nitride semiconductor layer, is provided above electron supply layer 24, and is provided at a position overlapping block layer 14 without overlapping first opening 20 in plan view of substrate 10. Threshold value adjustment layer 328 is provided between source electrode 34 and shielding layer 327 spaced apart from both source electrode 34 and shielding layer 327. Specifically, shortest distance D2 between threshold value adjustment layer 328 and source electrode 34 is shorter than shortest distance D1 between shielding layer 327 and source electrode 34. Both shortest distances D1 and D2 are distances in a gate length direction. The length of threshold value adjustment layer 328 in the gate length direction is shorter than D1-D2. Threshold value adjustment layer 328 is electrically separated from both source electrode 34 and shielding layer 327. Threshold value adjustment layer 328 is electrically connected to gate electrode 332.

Shielding layer 327 and threshold value adjustment layer 328 are formed by removing and separating a part of the nitride semiconductor film formed in the same step. Thus, shielding layer 327 and threshold value adjustment layer 328 have the same composition, thickness, carrier concentration, and the like. For example, each of shielding layer 327 and threshold value adjustment layer 328 is a film having a thickness of 200 nm, having a carrier concentration of 5 × 10¹⁷ cm⁻³ and containing p-type GaN as a main component.

Gate electrode 332 is an example of a first electrode, and is provided above threshold value adjustment layer 328. Gate electrode 332 is provided at a position overlapping block layer 14 without overlapping first opening 20 in plan view of substrate 10. Specifically, gate electrode 332 is provided in contact with the upper surface of threshold value adjustment layer 328.

Shielding electrode 338 is an example of a third electrode, and is provided above shielding layer 327 at a position overlapping first opening 20 in plan view of substrate 10. Shielding electrode 338 is electrically connected to source electrode 34 and shielding layer 327. Specifically, source wiring 50 is connected to shielding electrode 338, and is set to the same potential as source electrode 34.

Gate electrode 332 and shielding electrode 338 are formed by removing and separating a part of the conductive film formed in the same step. Thus, the main components of gate electrode 332 and shielding electrode 338 are the same. For example, each of gate electrode 332 and shielding electrode 338 contains, as a main component, a material to be ohmically connected to a p-type nitride semiconductor such as p-type GaN. For example, Pd, a Ni-based material, WSi, Au, or the like can be used as a material for forming gate electrode 332 and shielding electrode 338.

According to nitride semiconductor device 301 of the present exemplary embodiment, the threshold value of the transistor is determined by the flat portion of the channel outside first opening 20, and is not affected by the inclined portion of the channel. Thus, controllability of turning on and off the transistor can be enhanced. In addition, by providing shielding electrode 338 electrically connected to source electrode 34, shielding electrode 338 can terminate the line of electric force extending from drain electrode 36. Parasitic capacitance Cgd between the gate and the drain can be reduced, and the switching speed can be increased.

In addition, a source potential is supplied from shielding electrode 338 to shielding layer 327. Thus, a reverse bias can be applied to the pn junction between shielding layer 327 and 2DEG 25 via shielding electrode 338 and drain electrode 36. Thus, the breakdown voltage of the transistor can be increased.

Next, modifications of the fourth exemplary embodiment will be described. Hereinafter the difference from the fourth exemplary embodiment will be mainly described, and the common description will be omitted or simplified.

### First modification

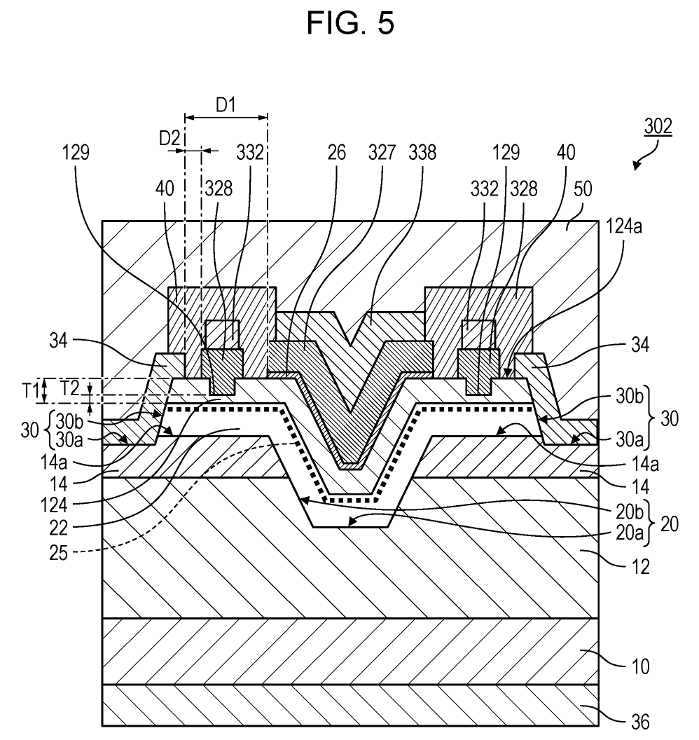

FIG. 5 is a cross-sectional view of nitride semiconductor device 302 according to a first modification of the fourth exemplary embodiment. As compared with nitride semiconductor device 301 illustrated in FIG. 4, nitride semiconductor device 302 illustrated in FIG. 5 includes electron supply layer 124 provided with recess 129 instead of electron supply layer 24.

Recess 129 is the same as that of the second exemplary embodiment, and is mainly different in that the recess is covered with threshold value adjustment layer 328 instead of non-overlapping portion 28B of p-type semiconductor layer 28. Since gate electrode 332 is electrically connected to threshold value adjustment layer 328, generation and disappearance of 2DEG 25 in a direction immediately below recess 129 can be controlled. Since the concentration of 2DEG 25 can be reduced in the direction immediately below recess 129, the threshold value of the transistor can be increased, and the normally-off operation can be easily realized.

In addition, because the portion of electron supply layer 124 where recess 129 is not provided can be thickened, the concentration of 2DEG 25 in the vicinity of the portion where recess 129 is not provided can be increased. Thus, the on-resistance can be reduced.

In this manner, according to nitride semiconductor device 302 of the present modification, it is possible to achieve both the normally-off operation and the reduction in the on-resistance.

### Second modification

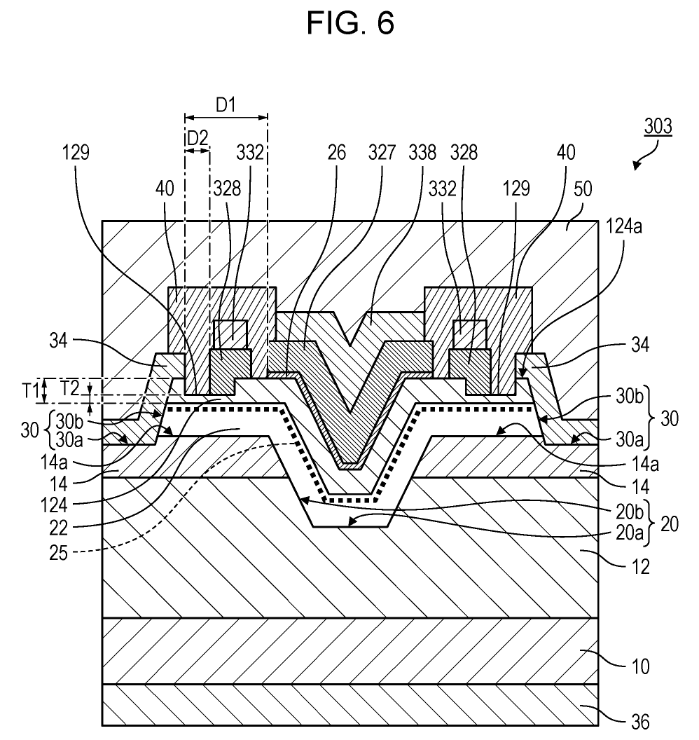

FIG. 6 is a cross-sectional view of nitride semiconductor device 303 according to a second modification of the fourth exemplary embodiment. Nitride semiconductor device 303 illustrated in FIG. 6 is different from nitride semiconductor device 302 illustrated in FIG. 5 mainly in the size of recess 129 and the position of the end of threshold value adjustment layer 328 on source electrode 34 side.

Specifically, the end of threshold value adjustment layer 328 on source electrode 34 side is positioned on the bottom surface of recess 129. That is, a part of the bottom surface of recess 129 is covered with threshold value adjustment layer 328, and the other part of the bottom surface of recess 129 is not covered with threshold value adjustment layer 328 but covered with insulating film 40.

The side surface of recess 129 and the side surface of source electrode 34 are formed to be flush with each other. As in FIG. 3, the shortest distance between recess 129 and source electrode 34 may be larger than 0 and shorter than shortest distance D2 between non-overlapping portion 28B and source electrode 34. Also in the present modification, the side surface of recess 129 on source electrode 34 side does not have to be provided. A part of source electrode 34 may be provided away from threshold value adjustment layer 328 in recess 129.

In nitride semiconductor device 303 according to the present modification, the concentration of 2DEG 25 decreases in a region immediately below recess 129, and 2DEG 25 can be eliminated in an OFF state. Since the area in which threshold value adjustment layer 328 electrically connected to gate electrode 32 and 2DEG 25 face each other is reduced, parasitic capacitance Cgs between the gate and the source can be reduced.

### Third modification

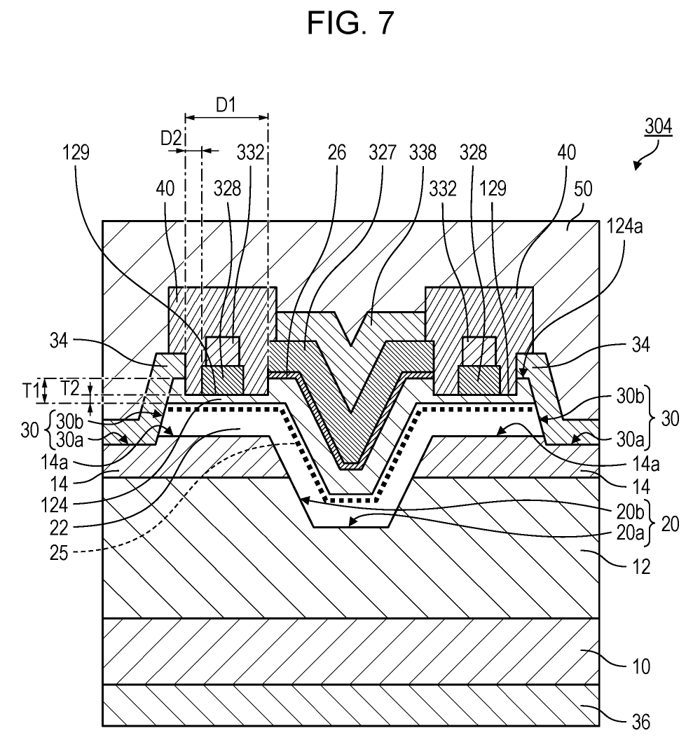

FIG. 7 is a cross-sectional view of nitride semiconductor device 304 according to a third modification of the fourth exemplary embodiment. Nitride semiconductor device 304 illustrated in FIG. 7 is different from nitride semiconductor device 303 illustrated in FIG. 6 mainly in the size of recess 129 and the position of the end of threshold value adjustment layer 328 on shielding layer 327 side.

Specifically, the end of threshold value adjustment layer 328 on shielding layer 327 side is positioned on the bottom surface of recess 129. That is, the bottom surface of recess 129 includes a portion that is not covered with threshold value adjustment layer 328 on both source electrode 34 side and shielding layer 327 side of threshold value adjustment layer 328.

The side surface of recess 129, the side surface of shielding layer 327, and the side surface of intermediate layer 26 are flush with each other. For example, patterning of shielding layer 327 and intermediate layer 26 and formation of recess 129 can be performed in the same etching process, and simplification of the production method can be realized.

In nitride semiconductor device 304 according to the present modification, the area in which threshold value adjustment layer 328 electrically connected to gate electrode 32 and 2DEG 25 face each other is further reduced, and thus, parasitic capacitance Cgs between the gate and the source can be further reduced.

### Fifth exemplary embodiment

Subsequently, a fifth exemplary embodiment will be described.

The fifth exemplary embodiment is mainly different from the first exemplary embodiment in that a source electrode is electrically connected to a p-type block layer via a p-type nitride semiconductor layer. Hereinafter, differences from the first exemplary embodiment will be mainly described, and description of common points will be omitted or simplified.

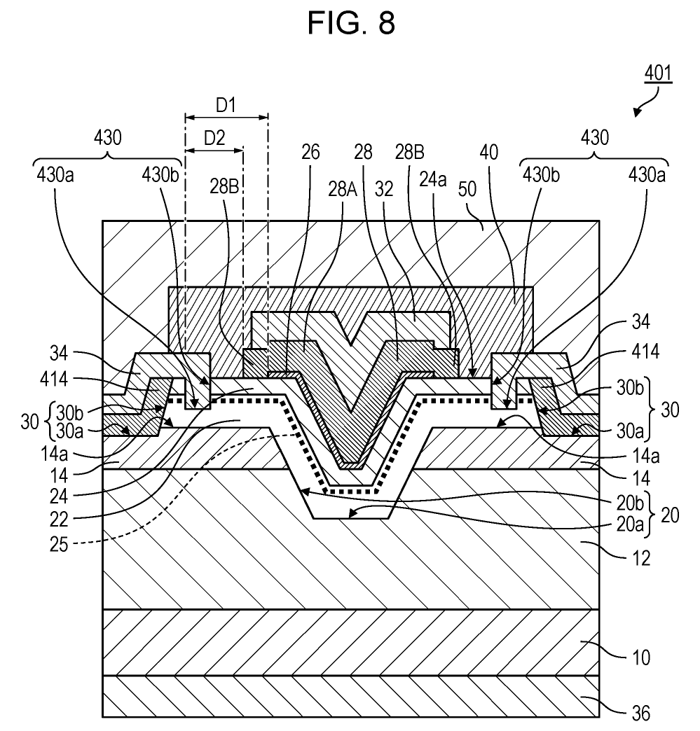

FIG. 8 is a cross-sectional view of nitride semiconductor device 501 according to the present exemplary embodiment. Nitride semiconductor device 401 illustrated in FIG. 8 includes contact layer 414 as compared with nitride semiconductor device 1 illustrated in FIG. 1. Furthermore, in nitride semiconductor device 401, third opening 430 is provided.

Contact layer 414 is an example of a p-type sixth nitride semiconductor layer, and is provided so as to be in contact with block layer 14 in second opening 30. Specifically, contact layer 414 contacts and covers bottom surface 30a and side surface 30b of second opening 30, and is in contact with block layer 14 at bottom surface 30a and a part of side surface 30b. Note that contact layer 414 may cover the vicinity of an opening end portion of second opening 30 in the upper surface of electron supply layer 24.

Contact layer 414 is a film including, as a main component, p-type GaN having a thickness of 200 nm and a carrier concentration of 5 × 10¹⁷ cm⁻³. Contact layer 414 can be formed in the same process as p-type semiconductor layer 28. Therefore, the composition and carrier concentration of contact layer 414 are the same as those of p-type semiconductor layer 28. Note that the thickness and carrier concentration of contact layer 414 are merely examples, and can be appropriately changed.

Contact layer 414 is formed by epitaxial growth after second opening 30 is formed. Bottom surface 30a of second opening 30 is subjected to etching damage when the second opening 30 is formed, whereas an upper surface of contact layer 414 is not subjected to etching damage. Therefore, in a case where source electrode 34 is brought into contact with contact layer 414, the contact resistance can be reduced as compared with the case of being brought into contact with block layer 14. In this manner, the potential of block layer 14 can be stabilized by electrically connecting source electrode 34 to block layer 14 via contact layer 414.

Third opening 430 is provided between second opening 30 and first opening 20 in plan view of substrate 10. Third opening 430 is an opening provided to reduce the contact resistance between source electrode 34 and 2DEG 25, and may be referred to as source opening. Third opening 430 penetrates electron supply layer 24 and reaches electron transport layer 22. For example, bottom surface 430a of third opening 430 is located lower than an interface between electron transport layer 22 and electron supply layer 24 and lower than a region where 2DEG 25 is generated. Therefore, 2DEG 25 is exposed on side surface 430b of third opening 430. By providing source electrode 34 so as to cover bottom surface 430a and side surface 430b of third opening 430, source electrode 34 and 2DEG 25 can be brought into contact with each other. This can reduce the contact resistance between source electrode 34 and 2DEG 25.

Note that, although FIG. 8 illustrates an example in which side surface 430b of third opening 430 is perpendicular to bottom surface 430a, side surface 430b may be inclined with respect to bottom surface 430a. Furthermore, third opening 430 does not necessarily penetrate electron supply layer 24. By thinning electron supply layer 24 located between source electrode 34 and 2DEG 25, the contact resistance can be reduced.

Note that, in nitride semiconductor device 401 according to the present exemplary embodiment, third opening 430 may not be provided. For example, contact layer 414 may not cover a portion in the vicinity of the interface between electron supply layer 24 and electron transport layer 22 in side surface 30b of second opening 30. In this case, source electrode 34 can be brought into contact with 2DEG 25 exposed on side surface 30b of second opening 30. The contact resistance to 2DEG 25 can be reduced without providing third opening 430.

Contact layer 414 and third opening 430 may be provided in nitride semiconductor device 101, 201, 301, 302, 303, or 304 according to the second to fourth exemplary embodiments and the modifications.

### Sixth exemplary embodiment

Subsequently, a sixth exemplary embodiment will be described.

The sixth exemplary embodiment is different from the first exemplary embodiment in that an opening is provided in the intermediate layer. Hereinafter, differences from the first exemplary embodiment will be mainly described, and description of common points will not be described or will be simplified.

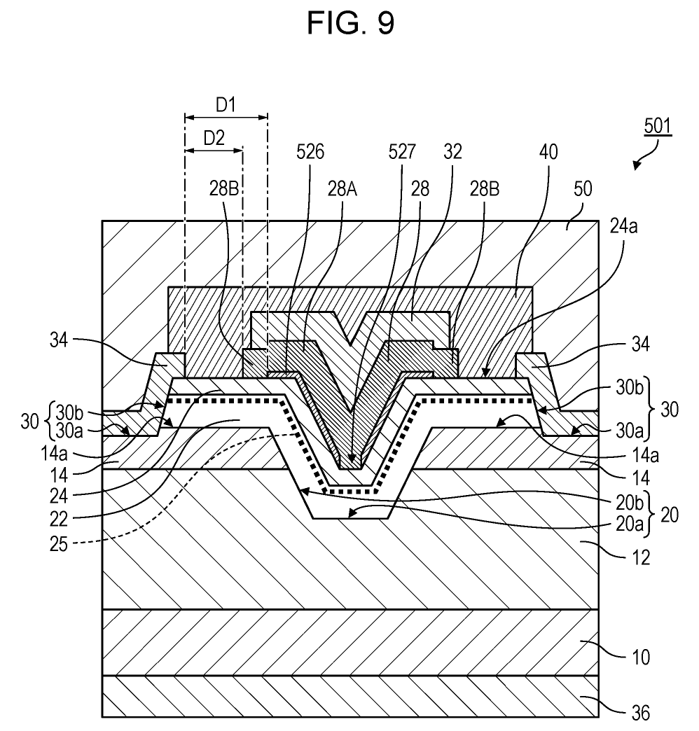

FIG. 9 is a cross-sectional view of nitride semiconductor device 501 according to the present exemplary embodiment. Nitride semiconductor device 501 illustrated in FIG. 9 includes intermediate layer 526 instead of intermediate layer 26 as compared with nitride semiconductor device 1 illustrated in FIG. 1.

Intermediate layer 526 has the same configuration as intermediate layer 26, and is different in that opening 527 is provided. Opening 527 is provided at a position overlapping at least a part of bottom surface 20a of first opening 20 in plan view of substrate 10. Since opening 527 is provided, intermediate layer 526 does not overlap at least a part of bottom surface 20a of first opening 20 in plan view of substrate 10. In the present exemplary embodiment, p-type semiconductor layer 28 is provided so as to fill opening 527, and thus, p-type semiconductor layer 28 is in contact with upper surface 24a of electron supply layer 24 in opening 527.

In opening 527, intermediate layer 526 is not provided between p-type semiconductor layer 28 and electron supply layer 24. Thus, electric field concentration due to reverse bias between the drain and the source can be alleviated by p-type semiconductor layer 28. As a result, the breakdown voltage of nitride semiconductor device 501 can be increased.

Opening 527 can be formed in the patterning process of intermediate layer 526. In the present exemplary embodiment, opening 527 is formed so as to expose the flat surface portion closest to substrate 10 in the upper surface of electron supply layer 24, but the present disclosure is not limited to this example. Opening 527 may be formed so as to expose a part of the inclined portion continuous from the flat surface portion closest to substrate 10 in the upper surface of electron supply layer 24.

Intermediate layer 526 provided with opening 527 may be provided instead of intermediate layer 26 of nitride semiconductor device 101, 201, 301, 302, 303, 304, or 401 according to the second to fifth exemplary embodiments and the modifications.

### Seventh exemplary embodiment

Subsequently, a seventh exemplary embodiment will be described.

The seventh exemplary embodiment is different from the first exemplary embodiment in that the conductivity type of the intermediate layer is i-type. Hereinafter, differences from the first exemplary embodiment will be mainly described, and description of common points will not be described or will be simplified.

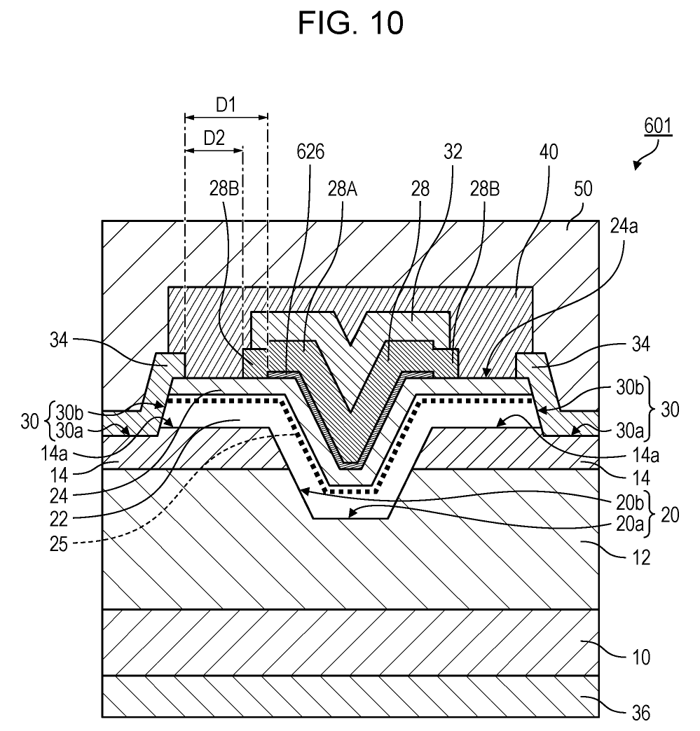

FIG. 10 is a cross-sectional view of nitride semiconductor device 601 according to the present exemplary embodiment. Nitride semiconductor device 601 illustrated in FIG. 10 includes intermediate layer 626 instead of intermediate layer 26 as compared with nitride semiconductor device 1 illustrated in FIG. 1.

Intermediate layer 626 has the same configuration as intermediate layer 26, and is different in that the conductivity type is not n-type but i-type. For example, intermediate layer 626 is a film containing i-type GaN as a main component. The film thickness of intermediate layer 626 is, for example, from 22 nm to 150 nm inclusive.

Intermediate layer 626 can suppress diffusion of p-type impurities from p-type semiconductor layer 28. Thus, intermediate layer 626 contains a p-type impurity. A diffusion layer containing the p-type impurity is formed along the upper surface of intermediate layer 626. The concentration of the p-type impurity in the diffusion layer gradually decreases, for example, from the upper surface to the lower surface.

Since intermediate layer 626 suppresses diffusion of the p-type impurity, channel depletion can be suppressed. Since the concentration of 2DEG 25 tends to be lower in the inclined portion of the channel than in the flat portion, the effect of suppressing depletion with intermediate layer 626 is effective. This can reduce the on-resistance.

Intermediate layer 26 or 526 according to each of the above-described exemplary embodiments and modifications has an n-type conductivity, but n-type intermediate layer 26 or 526 similarly has an effect of suppressing depletion. Since n-type intermediate layer 26 or 526 can cancel positive charges due to the p-type impurity, depletion of the channel can be suppressed.

Intermediate layer 626 whose conductivity type is i-type may be provided instead of intermediate layer 26 of nitride semiconductor device 101, 201, 301, 302, 303, 304, or 401 according to the second to fifth exemplary embodiments and the modifications, or intermediate layer 526 of nitride semiconductor device 501 according to the sixth exemplary embodiment.

### Other exemplary embodiments

The nitride semiconductor device according to one or more aspects has been described above on the basis of the exemplary embodiments, but the present disclosure is not limited to these exemplary embodiments. Configurations in which various modifications conceivable by those skilled in the art are applied to the present exemplary embodiments and configurations constructed by combining constituent elements in different exemplary embodiments are also included in the scope of the present disclosure without departing from the gist of the present disclosure.

For example, intermediate layer 26 may include, as a main component, a material other than the nitride semiconductor. For example, intermediate layer 26 may include, as a main component, a metal oxide such as gallium oxide or nickel oxide. Alternatively, intermediate layer 26 may include, as a main component, an insulating material such as silicon oxide or silicon nitride.

Furthermore, for example, second opening 30 may not be provided. In this case, source electrode 34 is provided on upper surface 24a of electron supply layer 24, and is electrically connected to 2DEG 25 via electron supply layer 24.

For example, in nitride semiconductor devices 1, 101, 201, 301, 302, 303, 304, 401, 501, and 601 according to the respective exemplary embodiments and modifications, a high-resistance layer having a resistance higher than that of block layer 14 may be provided between drift layer 12 and block layer 14. The high-resistance layer is, for example, a nitride semiconductor layer including carbon-doped GaN (C-GaN) as a main component. The carbon concentration of the high-resistance layer is, for example, more than or equal to 3 × 10¹⁷ cm⁻³, but may be more than or equal to 1 × 10¹⁸ cm⁻³. The high-resistance layer is provided in contact with each of drift layer 12 and block layer 14. The high-resistance layer may include n-type impurities such as Si. The concentration of the n-type impurities included in the high-resistance layer is lower than the carbon concentration and the oxygen concentration of the high-resistance layer, and may be, for example, less than or equal to 5 × 10¹⁶ cm⁻³, or less than or equal to 2 × 10¹⁶ cm⁻³. By providing the high-resistance layer, punch-through can be suppressed, and the withstand voltage can be increased. Note that, in a case where the high-resistance layer is formed, first opening 20 penetrates the high-resistance layer. As a result, since the high-resistance layer is not located on a path of the drain current when the FET is on, an increase in the on-resistance can be suppressed.

Furthermore, for example, drift layer 12 may have a graded structure in which the impurity concentration (donor concentration) gradually decreases from a substrate 10 side toward a block layer 14 side. Note that the donor concentration may be controlled by Si as a donor, or may be controlled by carbon as an acceptor that compensates for Si. Alternatively, drift layer 12 may have a stacked structure of a plurality of nitride semiconductor layers having different impurity concentrations. Specifically, the drift layer is formed into two layers, a layer having a low donor concentration is disposed below the block layer, and a layer having a high donor concentration is disposed on the substrate side. Then, by providing first opening 20 so as to penetrate the layer having a low donor concentration, a current flows through the layer having a high donor concentration through first opening 20 when the transistor is on, so that on-resistance can be reduced. On the other hand, when the transistor is off, a high electric field is held by the layer having a low donor concentration, so that both low on-resistance and high withstand voltage can be achieved.

For example, the nitride semiconductor device according to the present disclosure may be a lateral transistor. Specifically, any of the gate electrode, the source electrode, and the drain electrode may be provided above the substrate. In this case, the gate electrode is provided between the source electrode and the drain electrode. The nitride semiconductor device that is a lateral transistor does not have to include drift layer 12 or block layer 14.

Furthermore, for each of the exemplary embodiments described above, various changes, replacements, additions, omissions, and the like can be made within the scope of claims or equivalents thereof.

According to the present disclosure, on-resistance can be reduced.

The nitride semiconductor device according to the present disclosure is useful as, for example, a power device used in a power supply circuit, an inverter circuit, or the like of an electric device.

What is claimed is:

1. A nitride semiconductor device comprising:
a substrate;
a first nitride semiconductor layer disposed above the substrate;
a second nitride semiconductor layer disposed above the first nitride semiconductor layer, the second nitride semiconductor layer having a band gap larger than a band gap of the first nitride semiconductor layer;
a third nitride semiconductor layer of p-type disposed above the second nitride semiconductor layer;
a first electrode disposed above the third nitride semiconductor layer;
a second electrode disposed above the substrate and electrically connected to the first nitride semiconductor layer; and
an intermediate layer disposed between the second nitride semiconductor layer and the third nitride semiconductor layer,
wherein the third nitride semiconductor layer includes:
an overlapping portion that overlaps the intermediate layer in plan view of the substrate; and
a non-overlapping portion that does not overlap the intermediate layer in plan view of the substrate,
a shortest distance between the non-overlapping portion and the second electrode is shorter than a shortest distance between the overlapping portion and the second electrode, and
the first electrode is electrically connected to the non-overlapping portion.

2. The nitride semiconductor device according to claim 1, further comprising:
a fourth nitride semiconductor layer of n-type disposed above the substrate;
a fifth nitride semiconductor layer of p-type disposed above the fourth nitride semiconductor layer; and
a drain electrode disposed below the substrate, wherein
the first electrode is a gate electrode,
the second electrode is a source electrode,
the first nitride semiconductor layer and the second nitride semiconductor layer are disposed covering an inner surface of a first opening that penetrates the fifth nitride semiconductor layer and reaches the fourth nitride semiconductor layer and a portion above the fifth nitride semiconductor layer, and
the intermediate layer is disposed at a position overlapping the first opening in plan view of the substrate.

3. The nitride semiconductor device according to claim 2, wherein
the first electrode is disposed at a position overlapping the first opening in plan view of the substrate, and
the non-overlapping portion is disposed continuously from the overlapping portion.

4. The nitride semiconductor device according to claim 2, further comprising a third electrode disposed above the third nitride semiconductor layer at a position overlapping the first opening in plan view of the substrate and electrically connected to the second electrode,
wherein the first electrode is disposed at a position overlapping the fifth nitride semiconductor layer without overlapping the first opening in plan view of the substrate.

5. The nitride semiconductor device according to claim 4, wherein
the third electrode is electrically connected to the overlapping portion, and
the non-overlapping portion is disposed apart from the overlapping portion.

6. The nitride semiconductor device according to claim 2,
wherein the non-overlapping portion overlaps an upper surface of the fifth nitride semiconductor layer in plan view of the substrate.

7. The nitride semiconductor device according to claim 2, wherein
the second nitride semiconductor layer includes a recess at a position overlapping an upper surface of the fifth nitride semiconductor layer in plan view of the substrate, and
the non-overlapping portion is disposed in contact with at least a part of a bottom surface of the recess.

8. The nitride semiconductor device according to claim 7,
wherein an end of the non-overlapping portion on the second electrode side is positioned on the bottom surface of the recess.

9. The nitride semiconductor device according to claim 4, wherein
the second nitride semiconductor layer includes a recess at a position overlapping an upper surface of the fifth nitride semiconductor layer in plan view of the substrate, and
an end of the non-overlapping portion on the second electrode side and an end of the non-overlapping portion on a side opposite to the second electrode side are positioned on a bottom surface of the recess.

10. The nitride semiconductor device according to claim 2,
wherein the second electrode is electrically connected to the fifth nitride semiconductor layer via a second opening that penetrates the second nitride semiconductor layer and the first nitride semiconductor layer and reaches the fifth nitride semiconductor layer.

11. The nitride semiconductor device according to claim 10, further comprising a sixth nitride semiconductor layer of p-type disposed in contact with the fifth nitride semiconductor layer in the second opening,
wherein the second electrode is in contact with the sixth nitride semiconductor layer.

12. The nitride semiconductor device according to claim 2,
wherein the intermediate layer does not overlap at least a part of a bottom surface of the first opening in plan view of the substrate.

13. The nitride semiconductor device according to claim 1,
wherein the intermediate layer contains a nitride semiconductor as a main component.

14. The nitride semiconductor device according to claim 1,
wherein the intermediate layer has an n-type conductivity.

15. The nitride semiconductor device according to claim 1,
wherein the intermediate layer has an i-type conductivity.

16. The nitride semiconductor device according to claim 15,
wherein the intermediate layer contains a p-type impurity.

17. The nitride semiconductor device according to claim 1,
wherein the intermediate layer has a film thickness of from 22 nm to 150 nm inclusive.
